(19) United States
(12) Patent Application Publication
(10) Pub. No.: US 2008/0239852 A1
(43) Pub. Date: Oct. 2, 2008

(54) Test feature to improve DRAM charge retention yield

(76) Inventor: Reza Jazayeri, San Jose, CA (US)

Correspondence Address: INTEL CORPORATION;c/o INTELLEVATE, LLC, P.O. BOX 52050, MINNEAPOLIS, MN, 55402, US

(21) Appl. No.: 11/729,056

(22) Filed: Mar. 28, 2007

(51) Int. Cl. G11C 7/00

(52) U.S. Cl. 365/222

(57) ABSTRACT

In some embodiments, a design for test feature to improve DRAM charge retention yield is presented. In this regard, an apparatus is introduced comprising a first integrated circuit die, and a second integrated circuit die stacked together in a package, wherein the second integrated circuit die comprises a dynamic random access memory (DRAM) and circuitry to increase a refresh rate provided by a self refresh timer by a predetermined percentage. Other embodiments are also disclosed and claimed.

### FIELD OF THE INVENTION

Embodiments of the present invention generally relate to the field of stacked die packages, and, more particularly to a design for test feature to improve DRAM charge retention yield.

### BACKGROUND OF THE INVENTION

The charge retention time of DRAM based products is extremely temperature sensitive. 10° C. increase in the junction temperature of the DRAM may reduce its retention time by up to 50%. As a result test temperature excursions of a few degrees can result in increased yield loss. In Stacked-Chip Scale Packages (SCSP) where Flash and/or Processors are stacked with DRAM based products, the DRAM yield is of particular interest because a failing DRAM die results in the loss of a likely good Flash and/or a good Processor.

Standard test methodology requires temperature guardbands to be implemented at class test to account for test equipment and test temperature variability. In addition, during SCSP testing, even with a fixed case temperature, the actual junction temperature of the different die may be difficult to control exactly due to different test sequences and different stack-ups and it is not manufacturable to test the different die in the SCSP at different temperatures so testing has to be done at the highest (worst case) requirement.

The result of all of this is that in SCSP applications there is excess overkill of the DRAM die during class test for retention related tests. Such overkill cannot be compensated for with changing test voltage or other standard test parameters as the DRAM retention characteristics are not strongly voltage sensitive and the refresh frequencies cannot be controlled in self refresh mode (the DRAM autonomously refreshes itself in this mode and due to process variability each unit might have a slightly different self refresh frequency).

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a memory device with a design for test feature to improve DRAM charge retention yield, in accordance with one example embodiment of the invention;

FIG. 2 is a graphical illustration of a cross-sectional view of a stacked die package including a memory device with a design for test feature to improve DRAM charge retention yield, in accordance with one example embodiment of the invention;

FIG. 3 is a block diagram of an example electronic appliance suitable for implementing a memory device with a design for test feature to improve DRAM charge retention yield, in accordance with one example embodiment of the invention; and

FIG. 4 is a flowchart of an example method for testing DRAM charge retention, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a memory device with a design for test feature to improve DRAM charge retention yield, in accordance with one example embodiment of the invention. In accordance with the illustrated example embodiment, memory device 100 includes one or more of self refresh timer 102, refresh address and control 104, DRAM memory array 106, test mode counter 108, test mode enable input 110, and delay circuitry 112.

Self refresh timer 102 provides memory device 100 with a timer to refresh the contents of DRAM memory array 106. In one embodiment, self refresh timer 102 may include a crystal which periodically generates a signal to perform a refresh.

Refresh address and control 104 represents circuitry to refresh the contents of DRAM memory array 106. In one embodiment, refresh address and control 104 maintains a row pointer which is incremented and one row of DRAM memory array 106 is refreshed each time an indication is received to perform a refresh.

DRAM memory array 106 represents any type of DRAM used to store data and instructions. In one embodiment, DRAM memory array 106 may consist of Rambus DRAM (RDRAM). In another embodiment, DRAM memory array 106 may consist of double data rate synchronous DRAM (DDRSDRAM).

Test mode counter 108 represents circuitry (in conjunction with test mode enable input 110 and delay circuitry 112) to increase the refresh rate provided by self refresh 102 by a predetermined percentage, in one embodiment. One skilled in the art would appreciate that other circuitry may be used instead of test mode counter 108, and do not deviate in scope from the present invention. As shown, test mode counter 108 may maintain a count of refresh signals generated by self refresh timer 102. In one embodiment, test mode counter 108 is a four bit counter. In another embodiment, test mode counter 108 is a five bit counter.

Test mode enable input 110 represents a test signal that can activate an increase in refresh rate by a predetermined percentage. In one embodiment, one bit is used to turn the increased refresh rate on or off. In another embodiment, multiple bits may be used to vary the increase in refresh rate, for example by selecting a bit in test mode counter 108 to add an additional refresh.

Delay circuitry 112 represents circuitry to initiate an additional refresh signal to refresh address and control 104 after a certain count is reached by test mode counter 108. In one embodiment, delay circuitry 112 may initiate the additional refresh when the carry bit of test mode counter 108 is active. In another embodiment, delay circuitry 112 may initiate the additional refresh when a particular bit of test mode counter 108 indicated by test mode enable input 110 is active.

One skilled in the art would appreciate that memory device 100 has capable of having its refresh rate increased by a predetermined percentage with the introduction of an additional refresh signal for every x refresh signals generated by self refresh timer 102 (where x can be hardwired or set by control inputs).

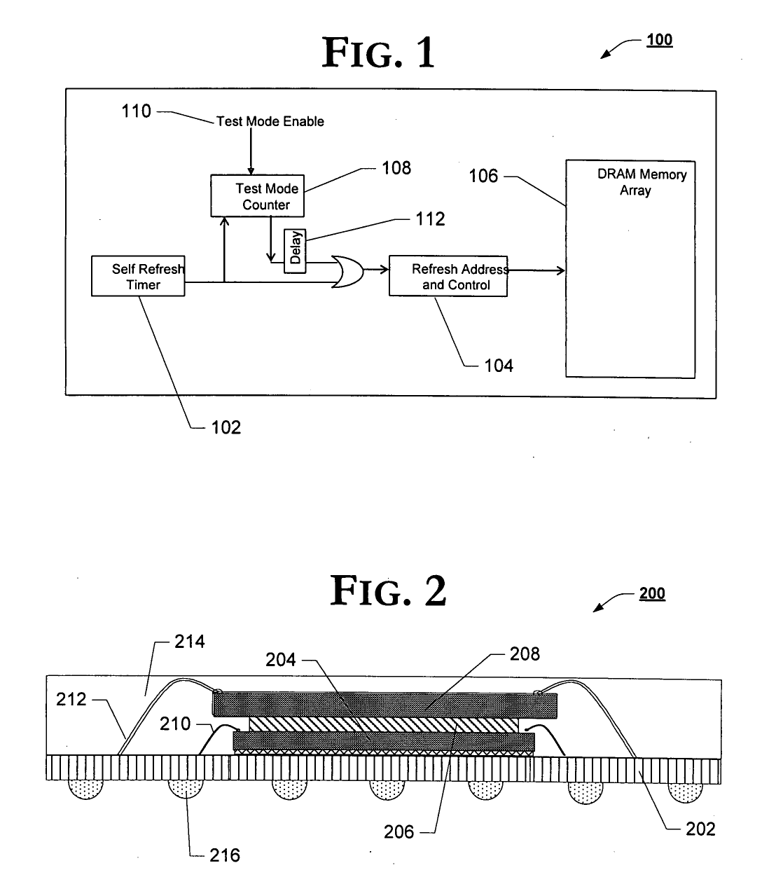

FIG. 2 is a graphical illustration of a cross-sectional view of a stacked die package including a memory device with a design for test feature to improve DRAM charge retention yield, in accordance with one example embodiment of the invention. As shown, package 200 includes one or more of substrate 202, bottom die 204, spacer 206, top die 208, bottom die wire 210, top die wire 212, mold 214, and solder ball 216.

Substrate 202 represents a substrate that may comprise multiple conductive layers laminated together. Substrate 202 may be laminated with dielectric material as part of a substrate build-up and may have insulated traces and vias routed through it.

Bottom die 204 represents an integrated circuit die. In one embodiment, bottom die 204 represents a memory device with a design for test feature to improve DRAM charge retention yield, such as memory device 100. Bottom die 204 is mechanically attached to substrate 202 by adhesive, which represents a thin-film attachment material. Top die 208 also represents an integrated circuit die. Top die 208 is mechanically attached to spacer 206 by adhesive. In one embodiment, top die 208 is a processor. In another embodiment, top die 208 is a flash memory device.

Spacer 206, if necessary, provides space for wirebonding of bottom die 204.

Top die wire 212 and bottom die wire 210 represent wirebonding that electrically couples top die 208 and bottom die 204, respectively, to contacts on top of substrate 202.

Mold 214 is used to protect dice 204 and 208 as well as wires 210 and 212. In one embodiment, mold 214 is an epoxy resin compound.

Solder ball 216 may be added to package 200 to allow package 200 to be coupled, for example to a substrate or printed circuit board. Other electrical interfaces besides solder balls may also be utilized.

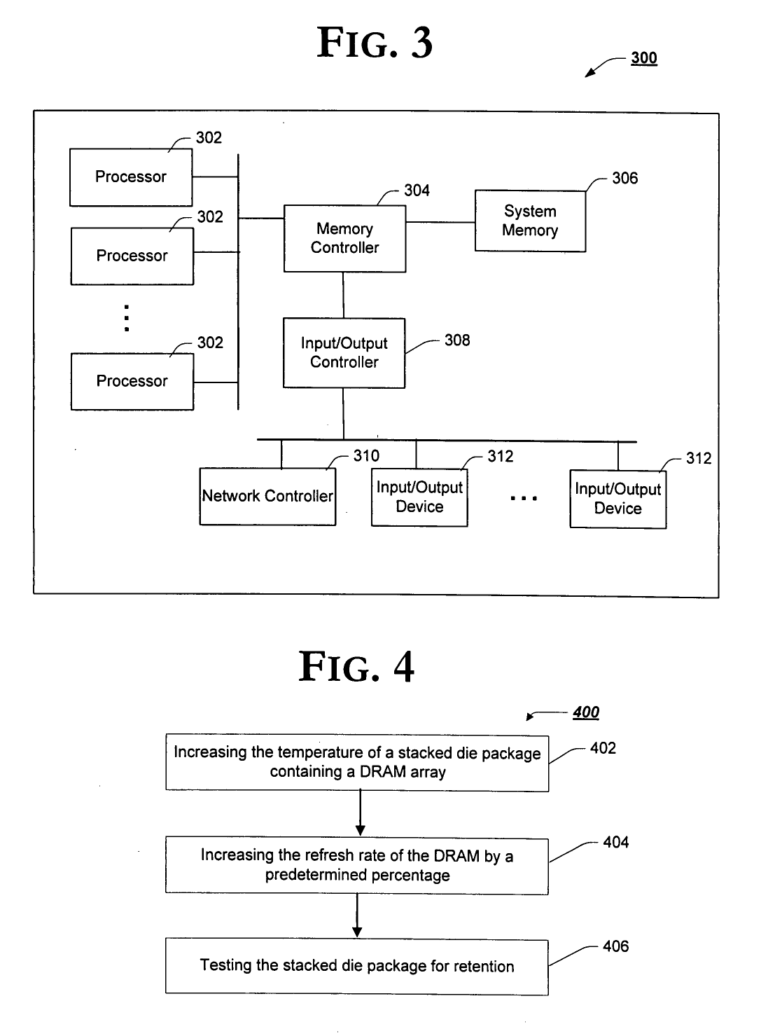

FIG. 3 is a block diagram of an example electronic appliance suitable for implementing a memory device with a design for test feature to improve DRAM charge retention yield, in accordance with one example embodiment of the invention. Electronic appliance 300 is intended to represent any of a wide variety of traditional and non-traditional electronic appliances, laptops, desktops, cell phones, wireless communication subscriber units, wireless communication telephony infrastructure elements, personal digital assistants, set-top boxes, or any electric appliance that would benefit from the teachings of the present invention. In accordance with the illustrated example embodiment, electronic appliance 300 may include one or more of processor(s) 302, memory controller 304, system memory 306, input/output controller 308, network controller 310, and input/output device(s) 312 coupled as shown in FIG. 3. Processor(s) 302 and system memory 306, or other integrated circuit components of electronic appliance 300, may be housed in a stacked die package including a memory device with a design for test feature to improve DRAM charge retention yield described previously as an embodiment of the present invention.

Processor(s) 302 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 302 are Intel® compatible processors. Processor(s) 302 may have an instruction set containing a plurality of machine level instructions that may be invoked, for example by an application or operating system.

Memory controller 304 may represent any type of chipset or control logic that interfaces system memory 306 with the other components of electronic appliance 300. In one embodiment, the connection between processor(s) 302 and memory controller 304 may be referred to as a front-side bus. In another embodiment, memory controller 304 may communicate over a point-to-point link.

System memory 306 may represent any type of memory device(s) used to store data and instructions that may have been or will be used by processor(s) 302. Typically, though the invention is not limited in this respect, system memory 306 will consist of dynamic random access memory (DRAM). In one embodiment, system memory 306 may consist of Rambus DRAM (RDRAM). In another embodiment, system memory 306 may consist of double data rate synchronous DRAM (DDRSDRAM).

Input/output (I/O) controller 308 may represent any type of chipset or control logic that interfaces I/O device(s) 312 with the other components of electronic appliance 300. In one embodiment, I/O controller 308 may be referred to as a south bridge. In another embodiment, I/O controller 308 may comply with the Peripheral Component Interconnect (PCI) Express™ Base Specification, Revision 1.0a, PCI Special Interest Group, released Apr. 15, 2003.

Network controller 310 may represent any type of device that allows electronic appliance 300 to communicate with other electronic appliances or devices. In one embodiment, network controller 310 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 310 may be an Ethernet network interface card.

Input/output (I/O) device(s) 312 may represent any type of device, peripheral or component that provides input to or processes output from electronic appliance 300.

FIG. 4 is a flowchart of an example method for testing DRAM charge retention, in accordance with one example embodiment of the invention. It will be readily apparent to those of ordinary skill in the art that although the following operations may be described as a sequential process, many of the operations may in fact be performed in parallel or concurrently. In addition, the order of the operations may be re-arranged without departing from the spirit of embodiments of the invention.

According to but one example implementation, the method of FIG. 4 begins with increasing (402) the temperature of a stacked die package containing a DRAM array. In one embodiment, the temperature may be increased to about 50 degrees Celsius or higher.

The method continues with increasing (404) the refresh rate of the DRAM by a predetermined percentage. In one embodiment, the refresh rate of the DRAM is increased by enabling test mode enable input 110. In another embodiment, the refresh rate of the DRAM is increased by selecting a bit of test mode counter 108 that when active while initiate a refresh in addition to refreshes initiated by self refresh timer 102. In one embodiment, the refresh increase percentage is between about 5 and 20 percent.

Then, testing (406) may be performed to verify retention of the DRAM array.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An apparatus comprising:
a first integrated circuit die; and
a second integrated circuit die stacked together in a package, wherein the second integrated circuit die comprises a dynamic random access memory (DRAM) and circuitry to increase a refresh rate provided by a self refresh timer by a predetermined percentage.

2. The apparatus of claim 1, wherein the first integrated circuit die comprises a flash memory.

3. The apparatus of claim 1, wherein the first integrated circuit die comprises a processor.

4. The apparatus of claim 1, wherein the circuitry to increase the refresh rate comprises a test mode input.

5. The apparatus of claim 1, wherein the circuitry to increase the refresh rate comprises a counter to count refreshes initiated by the self refresh timer and to initiate an additional refresh after a certain count is reached.

6. The apparatus of claim 5, wherein a carry bit of the counter initiates the additional refresh.

7. The apparatus of claim 5, further comprising circuitry to select a bit within the counter to initiate the additional refresh.

8. The apparatus of claim 1, further comprising a third integrated circuit die.

9. An electronic appliance comprising:
a processor;
a network controller; and
a DRAM memory, wherein the DRAM memory is stacked in a package with another integrated circuit die, the system memory including circuitry to increase a refresh rate provided by a self refresh timer by a predetermined percentage.

10. The electronic appliance of claim 9, wherein the another integrated circuit die comprises the processor.

11. The electronic appliance of claim 9, wherein the another integrated circuit die comprises a flash memory.

12. The electronic appliance of claim 9, wherein the circuitry to increase the refresh rate comprises a test mode input.

13. The electronic appliance of claim 9, wherein the circuitry to increase the refresh rate comprises a counter to count refreshes initiated by the self refresh timer and to initiate an additional refresh after a certain count is reached.

14. The electronic appliance of claim 13, wherein a carry bit of the counter initiates the additional refresh.

15. The electronic appliance of claim 13, further comprising circuitry to select a bit within the counter to initiate the additional refresh.

16. A method comprising:
increasing the temperature of a stacked die package containing a DRAM array;
increasing the refresh rate of the DRAM by a predetermined percentage; and
testing the stacked die package for retention.

17. The method of claim 16, wherein increasing the refresh rate comprises enabling a test mode input.

18. The method of claim 16, wherein increasing the refresh rate comprises selecting a bit of a counter which counts refreshes initiated by a self refresh timer and initiates an additional refresh after the bit count is reached.

19. The method of claim 16, wherein increasing the temperature comprises heating to about 50 degrees Celsius.

20. The method of claim 16, wherein increasing the refresh rate comprises increasing the refresh rate by between about 5 and 20 percent.
